(19) United States
(12) Patent Application Publication
(10) Pub. No.: US 2017/0287747 A1
(43) Pub. Date: Oct. 5, 2017

(54) Substrate Heating Device And Substrate Heating Method

(71) Applicant: BOE TECHNOLOGY GROUP CO., LTD., Beijing (CN)

(72) Inventors: Xiaoyong LU, Beijing (CN); Xiaowei XU, Beijing (CN); Yueping ZUO, Beijing (CN); Hongwei TIAN, Beijing (CN); Yu ZHANG, Beijing (CN); Chunping LONG, Beijing (CN)

(21) Appl. No.: 15/511,432

(22) PCT Filed: Feb. 15, 2016
(86) PCT No.: PCT/CN2016/073786

§ 371 Date: Mar. 15, 2017

(30) Foreign Application Priority Data
Mar. 16, 2015 (CN) 201510114199.5

(51) Int. Cl. H01L 21/67; H01L 21/66; H01L 21/324

(52) U.S. Cl. CPC H01L 21/67109; H01L 21/67248; H01L 21/324; H01L 22/26

(57) ABSTRACT

A substrate heating device and substrate heating method is disclosed. The device comprises: a heating layer for transferring heat; a transfer pipe for transferring a gas to a diffusion layer; the diffusion layer for enabling the gas to be uniformly distributed between a conducting layer and the heating layer; and the conducting layer for conducting the gas in the diffusion layer to below a substrate to be heated. The device can uniformly and fully heat the substrate to be heated, thus enabling the to-be-heated substrate to have a more uniform surface temperature, and achieving a better effect in an etching, deposition and/or sputtering process of the substrate to be heated.

### CROSS REFERENCE TO RELATED APPLICATIONS

This application claims the benefit and priority of Chinese Patent Application No. 201510114199.5 filed on Mar. 16, 2015, the entire content of which is incorporated herein by reference.

### BACKGROUND

The exemplary embodiments of the present disclosure relates to a substrate heating device and substrate heating method.

Currently, the manufacturing of a low temperature polysilicon (LTPS) thin film transistor (TFT) array substrate is developing toward high resolution and high performance In the heating process of the prior art, as shown in FIG. 1, the substrate is directly heated by a heating plate. However, the substrate may be unevenly heated, due to the fact that the heating plate itself has an uneven density or impurities. As a result, the temperature distribution of the substrate is uneven, leading to uneven thickness distribution of the film formed on the substrate. As shown in FIG. 2, the uniformity of thickness of the film formed on the substrate surface in the prior art can only reach 4.5%, affecting uniformity in the etching, deposition and/or sputtering process of the substrate.

### SUMMARY

Exemplary embodiments of the present disclosure provide a substrate heating device and substrate heating method, which can ensure a uniform temperature distribution over the substrate surface, thus achieving a better effect in an etching, deposition and/or sputtering process.

According to an aspect of the present disclosure, there is provided a substrate heating device. The substrate heating device comprises: a heating layer arranged to transfer heat; a transfer pipe arranged to transfer gas to a diffusion layer; the diffusion layer arranged to distribute the gas uniformly between a conducting layer and the heating layer; and the conducting layer arranged to conduct the gas in the diffusion layer to a substrate to be heated.

According to an embodiment of the present disclosure, the conducting layer is uniformly arranged with a plurality of through holes, via which the gas in the diffusion layer is conducted to the substrate to be heated.

According to an embodiment of the present disclosure, the substrate heating device further comprises: at least one lifter rod arranged to control distance between the substrate to be heated and the conducting layer.

According to an embodiment of the present disclosure, the substrate heating device further comprises: a limiting element arranged to limit the substrate to be heated to a preset range of heights.

According to an embodiment of the present disclosure, the substrate heating device further comprises: a flow control element arranged to control flow of the gas transferred to the diffusion layer by the transfer pipe.

According to an embodiment of the present disclosure, the substrate heating device further comprises: an opening control element arranged to control opening of at least one of the plurality of through holes.

According to an embodiment of the present disclosure, the substrate heating device further comprises: a temperature sensor arranged to detect temperature of top surface and/or bottom surface of the substrate to be heated.

According to an embodiment of the present disclosure, the substrate heating device further comprises: a feedback element arranged to transmit a signal to at least one of the at least one lifter rod, the flow control element and the opening control element to adjust heating parameters of the substrate to be heated, according to the temperature of the top surface and/or bottom surface of the substrate to be heated.

According to an embodiment of the present disclosure, the substrate heating device further comprises: a gas circulation element arranged to transfer the gas to a gas storage element after the gas heats the substrate to be heated; and the gas storage element, connected to the transfer pipe, arranged to store the gas and directing the stored gas into the transfer pipe.

According to an embodiment of the present disclosure, the substrate heating device further comprises: a buffer element, disposed at an outlet of the transfer pipe, arranged to reduce the speed of the gas transferred from the transfer pipe to the diffusion layer.

According to an embodiment of the present disclosure, the flow of gas conducted by each of the through holes is 5 to 20 sccm.

According to an embodiment of the present disclosure, the gas is argon.

According to another aspect of the present disclosure, there is provided a substrate heating method. The substrate heating method comprises: transferring gas to a diffusion layer through a transfer pipe; distributing the gas uniformly between a conducting layer and a heating layer through a diffusion layer; and conducting the gas in the diffusion layer to a substrate to be heated through a conducting layer.

According to an embodiment of the present disclosure, the conducting layer is uniformly arranged with a plurality of through holes, via which the gas in the diffusion layer is conducted to the substrate to be heated.

According to an embodiment of the present disclosure, the substrate heating method further comprises: controlling distance between the substrate to be heated and the conducting layer by at least one lifter rod, according to a received first command.

According to an embodiment of the present disclosure, the substrate heating method further comprises: limiting the substrate to be heated to a preset range of heights by a limiting element, according to a received second command.

According to an embodiment of the present disclosure, the substrate heating method further comprises: controlling flow of the gas transferred to the diffusion layer by the transfer pipe by a flow control element, according to a received third command.

According to an embodiment of the present disclosure, the substrate heating method further comprises: controlling opening of at least one of the plurality of through holes by an opening control element, according to a received fourth command.

According to an embodiment of the present disclosure, the substrate heating method further comprises: detecting temperature of top surface and/or bottom surface of the substrate to be heated by a temperature sensor.

According to an embodiment of the present disclosure, the substrate heating method further comprises: transmitting a signal to at least one of the at least one lifter rod, the flow control element and the opening control element to adjust heating parameters for the substrate to be heated by a feedback element, according to the temperature of the top surface and/or bottom surface of the substrate to be heated.

According to an embodiment of the present disclosure, the substrate heating method further comprises: transferring the gas to a gas storage element after the gas heats the substrate to be heated by a gas circulation element, according to a received fifth command; and storing the gas and directing the stored gas into the transfer pipe by the gas storage element connected to the transfer pipe.

According to an embodiment of the present disclosure, the substrate heating method further comprises: reducing the speed of the gas transferred from the transfer pipe to the diffusion layer by a buffer element disposed at an outlet of the transfer pipe, according to a received sixth command.

According to the exemplary embodiments of the present disclosure, the diffusion layer enables the gas to be uniformly distributed over the heating layer, so as to fully absorb the heat conducted by the heating layer and avoid the waste of heat; the conducting layer enables the gas which has absorbed the heat to be uniformly distributed below the substrate to be heated through the through holes, so as to uniformly and fully contact with and heat the substrate to be heated, thus enabling the to-be-heated substrate to have a more uniform surface temperature, and achieving a better effect in an etching, deposition and/or sputtering process of the substrate to be heated.

### BRIEF DESCRIPTION OF THE DRAWINGS

To make the technical solution of the embodiments of the present disclosure or the prior art more clear, the accompanying drawings for illustrating the embodiments of the present disclosure or the prior art are presented below. Apparently, the accompanying drawings are exemplary only, and those skilled in the art can derive other drawings from such accompanying drawings without creative efforts.

FIG. 1 illustrates a schematic diagram of a substrate heating device of the prior art;

FIG. 2 illustrates uniformity of thickness of a film formed on the substrate according to the device shown in FIG. 1;

FIG. 3 illustrates a schematic diagram of a substrate heating device according to an embodiment of the present disclosure;

FIG. 4 illustrates uniformity of thickness of a film formed on the substrate according to the device shown in FIG. 3;

FIG. 5 illustrates a schematic diagram of a conducting layer according to an embodiment of the present disclosure;

FIG. 6 illustrates a schematic diagram of a substrate heating device according to another embodiment of the present disclosure;

FIG. 7 illustrates an illustrative flow chart of a substrate heating method according to an embodiment of the present disclosure.

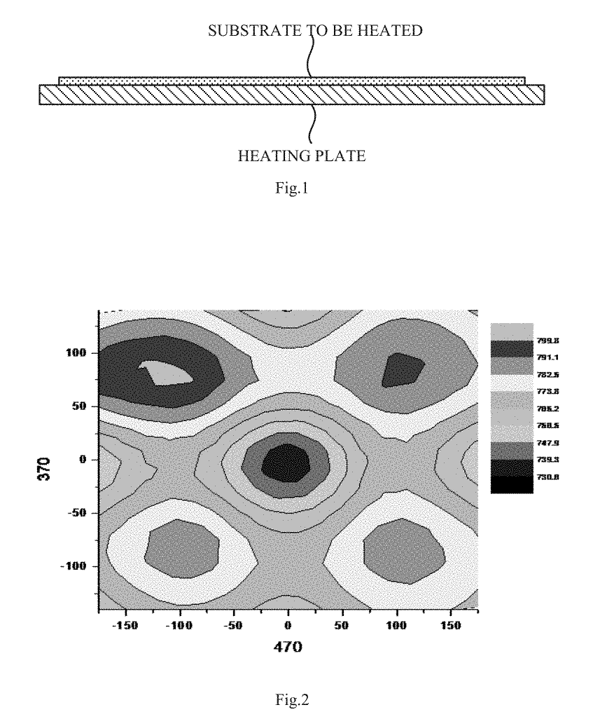

### DETAILED DESCRIPTION

With reference to the accompanying drawings, the technical solution of the embodiments of the present disclosure is described clearly and completely as following. Obviously, the given embodiments are only parts of the embodiments of the present disclosure, but not all embodiments of the present disclosure. Based on the embodiments of the present disclosure, all other embodiments which can be obtained without devoting a creative work by those skilled in the art should be deemed to fall into the scope of the present disclosure.

It should be noted that, in the drawings, sizes of layer and region may be enlarged in order to make the diagrams clear. It can be understood that, when an element or a layer is called to be located “above” the other element or layer, it may be directly located on the other element, or there may be an intermediate layer. In addition, it can be understood that, when an element or a layer is called to be located “below” the other element or layer, it may be directly located below the other element, or there may be more than one intermediate layers or elements. In addition, it can be understood that, when a layer or an element is called to be located “between” two elements or layers, it may be a unique layer between the two elements or layers, or there may be more than one intermediate layers or elements.

Unless otherwise specified, the term “a plurality of” refers to two or more.

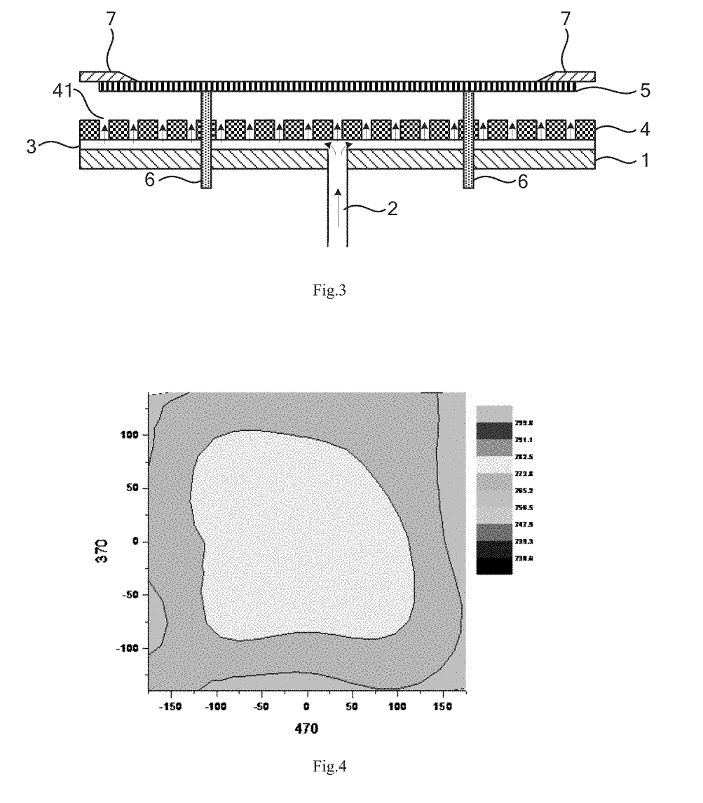

As shown in FIG. 3, the substrate heating device according to an embodiment of the present disclosure comprises: a heating layer 1 arranged to transfer heat; a transfer pipe 2 arranged to transfer gas to a diffusion layer 3; the diffusion layer 3, disposed above the heating layer 1, arranged to distribute the gas uniformly between a conducting layer 4 and the heating layer 1; and the conducting layer 4, disposed on the diffusion layer 3, arranged to conduct the gas in the diffusion layer 3 to a substrate 5 to be heated.

According to an embodiment of the present disclosure, as shown in FIG. 5, the conducting layer is uniformly arranged with a plurality of through holes 41, via which the gas in the diffusion layer 3 is conducted to the bottom of the substrate to be heated.

By the diffusion layer 3, the gas conducted from the transfer pipe 2 can be uniformly distributed over the heating layer 1, so as to fully absorb the heat conducted by the heating layer 1 and avoid the waste of heat. By the through holes 41 arranged uniformly on the conducting layer 4, the gas which has absorbed the heat can be uniformly distributed below the substrate 5 to be heated through the through holes 41 (the direction of the gas flow is shown by the arrow in the figure). Therefore, the gas can uniformly and fully contact with the substrate 5 to be heated, and heat the substrate 5 to be heated. Temperature of top surface of the substrate 5 to be heated become more uniform, so as to obtain a better effect in an etching, deposition and/or sputtering process of the substrate 5 to be heated.

As shown in FIG. 4, by heating the substrate 5 to be heated according to the embodiment of the present disclosure, uniformity of thickness of the film arranged on the substrate 5 to be heated becomes 1.3%, which is obviously superior to the prior art (in which the corresponding uniformity is 4.5%).

When the heating gas diffuse to the substrate 5 to be heated, the gas conducted from different through holes 41 become uniform, such that the substrate 5 can be uniformly heated. Therefore, the structure according to the embodiment of the present disclosure provides the substrate 5 to be heated a better heating effect, even if the heating layer 1 itself has an uneven temperature distribution.

According to an embodiment of the present disclosure, the substrate heating device further comprises: at least one lifter rod 6, in contact with the substrate 5 to be heated, arranged to control distance between the substrate 5 to be heated and the conducting layer 4. As shown in FIG. 5, a plurality of lifter rods 6 (for example, four lifter rods 6) may be arranged to pass through the conducting layer 4. In other words, the conducting layer 4 may be arranged with a plurality of holes, the shape thereof match with that of the lifter rods 6. It should be noted that the number and shape of the lifter rods 6 can be set up as needed.

The lifter rod 6 makes it possible to control the distance between the substrate 5 to be heated and the conducting layer 4, so as to control the heating strength of the heating gas for heating the substrate 5 to be heated. Moving the lifter rod 6 upward increases the distance between the substrate 5 to be heated and the conducting layer 4, such that the concentration of the heating gas below the substrate 5 to be heated is reduced. Therefore, the heating strength of the substrate 5 to be heated is reduced. On the contrary, the heating strength of the substrate 5 may be increased.

According to an embodiment of the present disclosure, the substrate heating device further comprises: a limiting element 7 arranged to limit the substrate 5 to be heated to a preset range of heights, so as to etch, deposit and/or sputter the substrate 5. As shown in FIG. 3, the limiting elements 7 may be present in pairs on both sides of the substrate 5 to be heated. In this way, the substrate 5 to be heated can be prevented from being raised too high by the lifter rod 6 and is thus maintained in the operable process of the etching, deposition and/or sputtering process.

It should be noted that although the illustrated limiting elements 7 contact with the substrate 5 to be heated so as to limit the substrate 5, a distance sensor may be adopted to detect and limit the position of the substrate 5 without contacting with it.

According to an embodiment of the present disclosure, the substrate heating device further comprises: a flow control element (not shown) arranged to control flow of the gas transferred from the transfer pipe 2 to the diffusion layer 3. By controlling the flow of the transferred gas, it can regulate the concentration of gas transferred to the substrate 5 to be heated, whereby the heating strength of the heating gas can be controlled.

According to an embodiment of the present disclosure, the substrate heating device further comprises: an opening control element (not shown) arranged to control opening of at least one of the plurality of through holes 41. By controlling the opening of the through holes 41, it can precisely control the concentration of gas transferred to the substrate 5 to be heated, whereby the heating strength of the heating gas can be precisely controlled.

According to an embodiment of the present disclosure, the substrate heating device further comprises: a temperature sensor (not shown) arranged to detect temperature of top surface and/or bottom surface of the substrate 5 to be heated, and to display the value thereof. The temperature sensor may include a plurality of detecting terminals to detect temperature from a plurality of positions on the substrate 5 to be heated, so as to determine the temperature of top surface and/or bottom surface of the substrate 5 to be heated in a more accurate way.

According to an embodiment of the present disclosure, the substrate heating device further comprises: a feedback element (not shown) arranged to transmit a signal to at least one of the at least one lifter rod, the flow control element and the opening control element to adjust heating parameters for the substrate 5 to be heated, according to the temperature of the top surface and/or bottom surface of the substrate 5 to be heated. For example, the opening of the through holes in a certain region of the conducting layer 4 may be controlled by the opening control element, so as to regulate the heating strength of corresponding region of the substrate 5 to be heated. Also, the heating strength of corresponding region of the substrate 5 to be heated may be regulated by simply changing the height of some of the plurality of lifter rods.

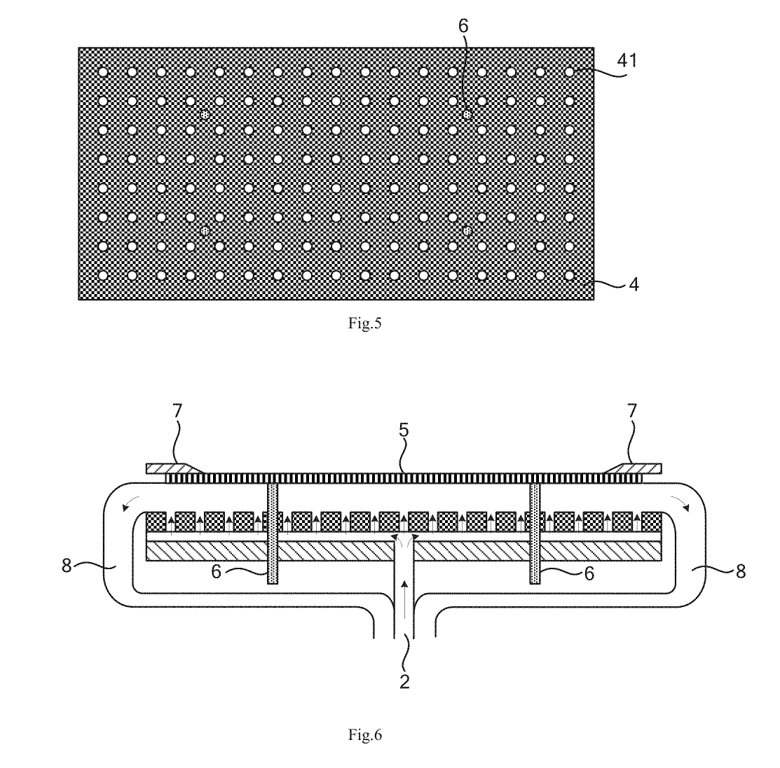

According to an embodiment of the present disclosure, as shown in FIG. 6, the substrate heating device further comprises: a gas circulation element 8 (for example, a transfer pipe) arranged to transfer the gas to a gas storage element after the gas heats the substrate 5 to be heated; and the gas storage element (not shown), connected to the transfer pipe 2, arranged to store the gas and direct the stored gas into the transfer pipe 2.

Since the gas still has remaining heat after heating the substrate 5 to be heated, it is possible to recycle the gas in order to improve the heat energy efficiency.

According to an embodiment of the present disclosure, the substrate heating device further comprises: a buffer element (not shown), disposed at an outlet of the transfer pipe 2, arranged to reduce the speed of the gas transferred from the transfer pipe 2 to the diffusion layer 3.

Using with the buffer element, it is possible to avoid the gas conducted from the transfer pipe 2 from being directly conducted through the through holes in the conducting layer 4, whereby the gas conducted from the transfer pipe 2 can be evenly distributed over the heating layer to fully absorb the heat conducted by the heating layer 1, avoiding the waste of heat.

According to an embodiment of the present disclosure, the flow of gas conducted by each of the through holes 41 is 5 to 20 sccm. In this way, the gas would not flow through the substrate 5 to be heated too quickly, so that the substrate 5 can be fully heated.

According to an embodiment of the present disclosure, the gas is argon.

It would be appreciated that other noble gases can be used as the heating gas as needed. As compared with other noble gases, argon can be obtained in a relative easy way and is usually used as the heating gas. Argon, on one hand, does not react with the substrate 5 to be heated and, on the other hand, has superior thermal conductivity which achieves better heating effect for the substrate 5 to be heated.

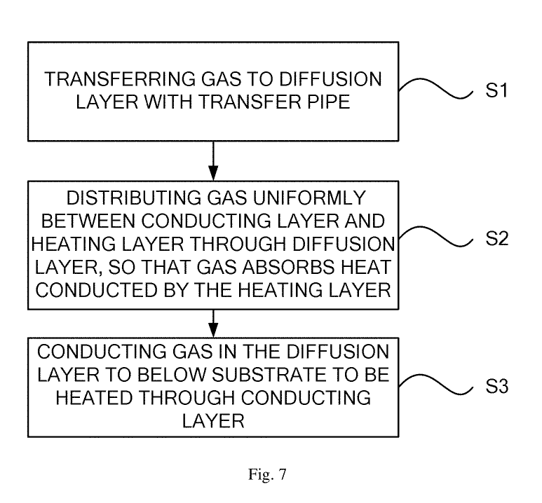

As shown in FIG. 7, the substrate heating method according to an embodiment of the present disclosure comprises: a step S1 of transferring gas to a diffusion layer 3 through a transfer pipe 2; a step S2 of distributing the gas to be uniformly between a conducting layer 4 and a heating layer 1 through a diffusion layer 3, so that the gas absorbs the heat conducted by the heating layer 1; and a step S3 of conducting the gas in the diffusion layer 3 to a substrate 5 to be heated through the conducting layer 4.

According to an embodiment of the present disclosure, the conducting layer 4 is uniformly arranged with a plurality of through holes 41, via which the gas in the diffusion layer 3 is conducted to the substrate 5 to be heated, so as to heat the substrate 5.

According to an embodiment of the present disclosure, the substrate heating method further comprises: controlling distance between the substrate 4 to be heated and the conducting layer 4 by at least one lifter rod 6 in contact with the substrate to be heated, according to a received first command (for example, a lifting command).

According to an embodiment of the present disclosure, the substrate heating method further comprises: limiting the substrate 5 to be heated to a preset range of heights by a limiting element 7, so as to subject the substrate 5 to an etching, deposition and/or sputtering process, according to a received second command (for example, a limiting command).

According to an embodiment of the present disclosure, the substrate heating method further comprises: controlling flow of the gas transferred to the diffusion layer 3 by the transfer pipe 2 by a flow control element, according to a received third command (for example, a flow control command).

According to an embodiment of the present disclosure, the substrate heating method further comprises: controlling opening of at least one through hole 41 of the plurality of through holes 41 by an opening control element, according to a received fourth command (for example, an opening control command).

According to an embodiment of the present disclosure, the substrate heating method further comprises: detecting temperature of top surface and/or bottom surface of the substrate 5 to be heated by a temperature sensor, so as to display the detected temperature value.

According to an embodiment of the present disclosure, the substrate heating method further comprises: transmitting a signal to at least one lifter rod, and/or the flow control element, and/or the opening control element to adjust heating parameters for the substrate 5 to be heated by a feedback element, according to the temperature of the top surface and/or bottom surface of the substrate 5 to be heated.

According to an embodiment of the present disclosure, the substrate heating method further comprises: transferring the gas to a gas storage element after the gas heats the substrate 5 to be heated by a gas circulation element 8, according to a received fifth command (for example, a gas circulation command); and storing the gas and directing the stored gas into the transfer pipe 2 by the gas storage element connected to the transfer pipe 2.

According to an embodiment of the present disclosure, the substrate heating method further comprises: reducing the speed of the gas transferred from the transfer pipe 2 to the diffusion layer 3 by a buffer element disposed at an outlet of the transfer pipe 2, according to a received sixth command (for example, a buffer command).

The technical solution of the present disclosure has been described with reference to the drawings. In the relevant technical fields, it is difficult to ensure uniformity of the substrate surface temperature, since the substrate is heated by directly contacting the heating plate with the substrate. In contrast, according to the technical solution of the present disclosure, the gas absorbs the heat and is then transferred to an area below the substrate to be heated, so as to uniformly and fully contact with the substrate to be heated, and heat the substrate to be heated. Therefore, the substrate to be heated can obtain a more uniform surface temperature, achieving a better effect in an etching, deposition and/or sputtering process of the substrate to be heated.

The substrate heated according to the present disclosure may be employed in manufacturing various display devices, such as any product or component having display function, such as an electronic paper, a mobile phone, a tablet, a TV, a laptop, a digital frame, a navigator, etc.

The foregoing descriptions are merely exemplary specific embodiments of the present disclosure, but are not intended to limit the protection scope of the present disclosure. Any modification or replacement easily thought of by persons skilled in the art without departing from the technical scope of the present disclosure shall all fall into the protection scope of the present disclosure. Therefore, the protection scope of the present disclosure should be subject to the protection scope of the claims.

1. A substrate heating device, comprising:
a heating layer arranged to transfer heat;
a transfer pipe arranged to transfer gas to a diffusion layer;
the diffusion layer arranged to distribute the gas uniformly between a conducting layer and the heating layer; and
the conducting layer arranged to conduct the gas in the diffusion layer to a substrate to be heated.

2. The substrate heating device according to claim 1, wherein the conducting layer is uniformly arranged with a plurality of through holes, via which the gas in the diffusion layer is conducted to the substrate to be heated.

3. The substrate heating device according to claim 1, further comprising:
at least one lifter rod arranged to control distance between the substrate to be heated and the conducting layer.

4. The substrate heating device according to claim 1, further comprising:
a limiting element arranged to limit the substrate to be heated to a preset range of heights.

5. The substrate heating device according to claim 1, further comprising:
a flow control element arranged to control flow of the gas transferred to the diffusion layer by the transfer pipe.

6. The substrate heating device according to claim 2, further comprising:
an opening control element arranged to control opening of at least one of the plurality of through holes.

7. The substrate heating device according to claim 1, further comprising:
a temperature sensor arranged to detect temperature of top surface and/or bottom surface of the substrate to be heated.

8. The substrate heating device according to claim 7, further comprising:
a feedback element arranged to transmit a signal to at least one of the at least one lifter rod, the flow control element and the opening control element to adjust heating parameters for the substrate to be heated, according to the temperature of the top surface and/or bottom surface of the substrate to be heated.

9. The substrate heating device according to claim 1, further comprising:
a gas circulation element arranged to transfer the gas to a gas storage element after the gas heats the substrate to be heated; and
the gas storage element, connected to the transfer pipe, arranged to store the gas and direct the stored gas into the transfer pipe.

10. The substrate heating device according to claim 1, further comprising:
a buffer element, disposed at an outlet of the transfer pipe, arranged to reduce the speed of the gas transferred from the transfer pipe to the diffusion layer.

11. The substrate heating device according to claim 2, wherein the flow of gas conducted by each of the through holes is 5 to 20 sccm.

12. The substrate heating device according to claim 1, wherein the gas is argon.

13. A substrate heating method, comprising:
transferring gas to a diffusion layer through a transfer pipe;
distributing the gas uniformly between a conducting layer and a heating layer through a diffusion layer; and
conducting the gas in the diffusion layer to a substrate to be heated through a conducting layer.

14. (canceled)

15. The substrate heating method according to claim 13, further comprising:
controlling distance between the substrate to be heated and the conducting layer by at least one lifter rod, according to a received first command.

16. The substrate heating method according to claim 13, further comprising:
limiting the substrate to be heated to a preset range of heights by a limiting element, according to a received second command.

17. The substrate heating method according to claim 13, further comprising:
controlling flow of the gas transferred to the diffusion layer by the transfer pipe by a flow control element, according to a received third command.

18. (canceled)

19. The substrate heating method according to claim 13, further comprising:
detecting temperature of top surface and/or bottom surface of the substrate to be heated by a temperature sensor.

20. The substrate heating method according to claim 19, further comprising:
transmitting a signal to at least one of the at least one lifter rod, the flow control element and the opening control element to adjust heating parameters for the substrate to be heated by a feedback element, according to the temperature of the top surface and/or bottom surface of the substrate to be heated.

21. The substrate heating method according to claim 13, further comprising:
transferring the gas to a gas storage element after the gas heats the substrate to be heated by a gas circulation element, according to a received fifth command; and
storing the gas and directing the stored gas into the transfer pipe by the gas storage element connected to the transfer pipe.

22. The substrate heating method according to claim 13, further comprising:
reducing the speed of the gas transferred from the transfer pipe to the diffusion layer by a buffer element disposed at an outlet of the transfer pipe, according to a received sixth command.
